(19) United States
(12) Patent Application Publication
(10) Pub. No.: US 2010/0283570 A1
(43) Pub. Date: Nov. 11, 2010

(54) NANO-ENCAPSULATED MAGNETIC PARTICLE COMPOSITE LAYERS FOR INTEGRATED SILICON VOLTAGE REGULATORS

(76) Inventors: Adrien R. Lavoie, Beaverton, OR (US); Arnel M. Fajardo, Beaverton, OR (US)

Correspondence Address: Rahul D. Engineer;Intel Corporation, c/o Intellevate, LLC, P.O. Box 52050, Minneapolis, MN, 55402, US

(21) Appl. No.: 11/940,142

(22) Filed: Nov. 14, 2007

(51) Int. Cl. H01F 5/00; H05K 3/00

(52) U.S. Cl. 336/200; 427/97.6; 427/97.4

(57) ABSTRACT

A method of forming an integrated silicon voltage regulator (ISVR) comprises providing a nano-encapsulated magnetic particle (NEMP) suspension, depositing a first layer of the NEMP suspension on an integrated circuit (IC) device, curing the first layer of the NEMP suspension to form a first NEMP composite layer, forming at least one inductor wire on the NEMP composite layer, depositing an interlayer dielectric material over the inductor wire, depositing a second layer of the NEMP suspension on the interlayer dielectric material, and curing the second layer of the NEMP suspension to form a second NEMP composite layer.

### BACKGROUND

In the manufacture of integrated circuit devices, voltage regulators are generally located separate from the integrated circuit die. On die voltage regulators, known as integrated silicon voltage regulators (ISVR), are highly desired. However, issues such as eddy currents tend to appear in conventional metal magnetic films used for ISVR, thereby causing reliability issues.

Conventional off-die voltage regulators tend to be relatively large and consume considerable power. Off-die voltage regulators are also slow relative to ISVR devices due to impedance caused by the length of the connection to the integrated circuit transistors. This slowness causes a bottleneck as integrated circuit devices are made smaller and faster. Accordingly, improved ISVR devices are needed to reduce eddy currents and eliminate the need for off-die voltage regulators.

### BRIEF DESCRIPTION OF THE DRAWINGS

FIG. 1 is a method of forming an integrated silicon voltage regulator using a nano-encapsulated magnetic particle suspension in accordance with an implementation of the invention.

FIGS. 2A to 2D illustrate structures that are formed when the method of FIG. 1 is carried out.

FIG. 3 illustrates an integrated silicon voltage regulator formed using the nano-encapsulated magnetic particle suspension.

### DETAILED DESCRIPTION

Described herein are systems and methods of forming an integrated silicon voltage regulator (ISVR) using a nano-encapsulated magnetic particle suspension. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Implementations of the invention provide structures and fabrication methods for an ISVR device formed using nano-encapsulated magnetic particles dispersed within a dielectric material. For ease of reference, this mixture of magnetic particles within a dielectric material will be referred to herein as a “nano-encapsulated magnetic particle suspension,” or simply as the “suspension”. The magnetic particles may be formed using metals such as cobalt, nickel, and iron that are encased within a protective nano-encapsulation shell. The nano-encapsulation shell may be formed using materials that include, but are not limited to, aluminum oxide, silicon dioxide, silicon nitride, tantalum nitride, titanium nitride, fluorinated silicon dioxide, carbon doped oxide, tetraethylorthosilicate (TEOS), borophosphosilicate glass (BPSG), fluorosilicate glass (FSG), spin-on glass (SOG), low-k materials, high-k materials, organic polymers such as perfluorocyclobutane and polytetrafluoroethylene, inorganic polymers, and organosilicates such as silsesquioxane, siloxane, and organosilicate glass. The nano-encapsulation shell protects the magnetic particles from oxidation and loss of magnetic moment.

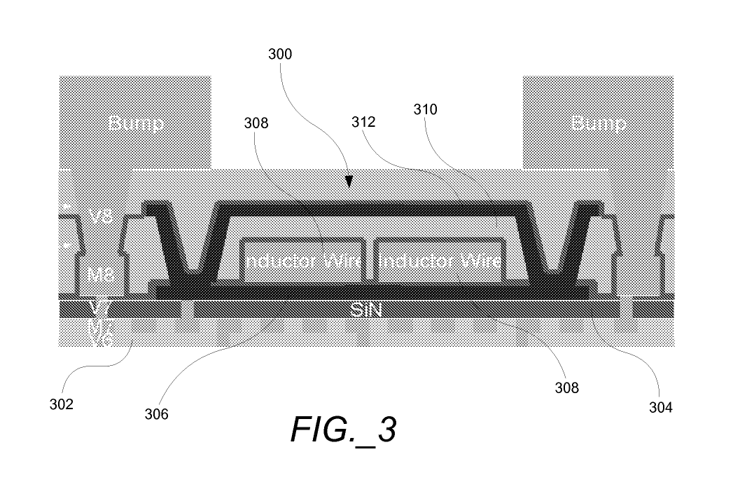

For reference, FIG. 3 illustrates an integrated silicon voltage regulator (ISVR) device 300 that is formed on or within an integrated circuit structure 302. Here, the ISVR 300 is formed on a passivation layer 304 of the integrated circuit structure 302. A first magnetic core material (MCM) layer 306 of the ISVR 300 is formed on this passivation layer 304. Two inductor wires 308 are formed on the first MCM layer 306. An interlayer dielectric material 310 is deposited over the inductor wires 308. A second MCM layer 312 is formed on the interlayer dielectric material 310 over the inductor wires 308. In accordance with implementations of the invention, both the first MCM layer 306 and the second MCM layer 312 are formed using the nano-encapsulated magnetic particle suspension of the invention.

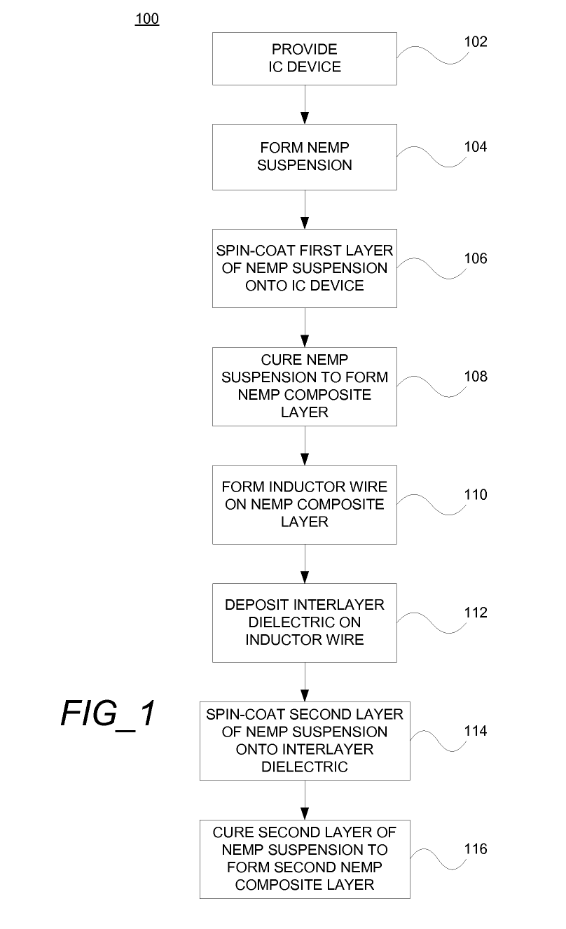

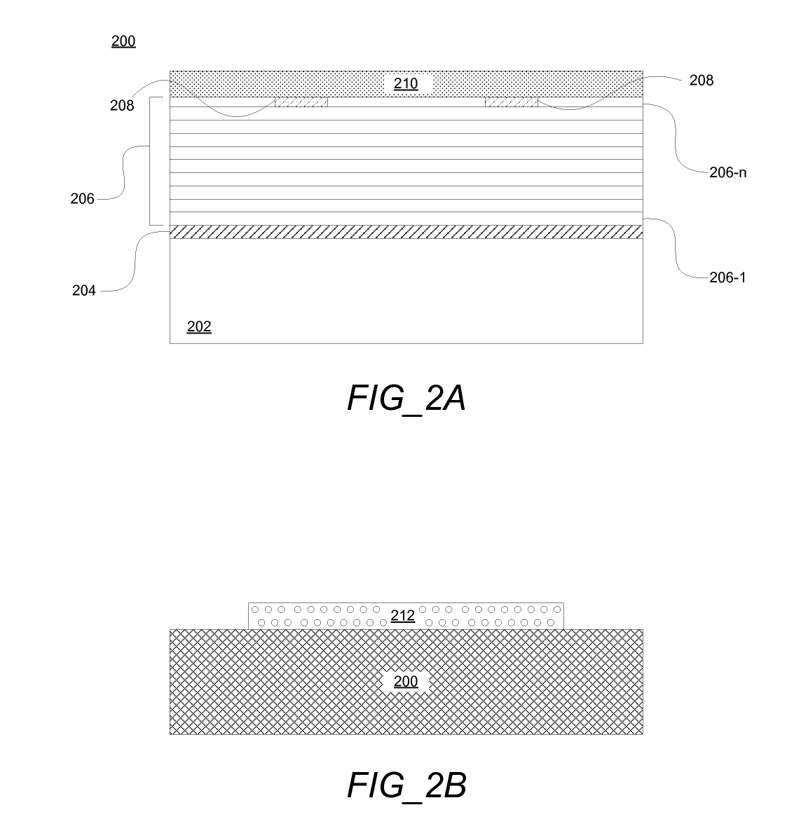

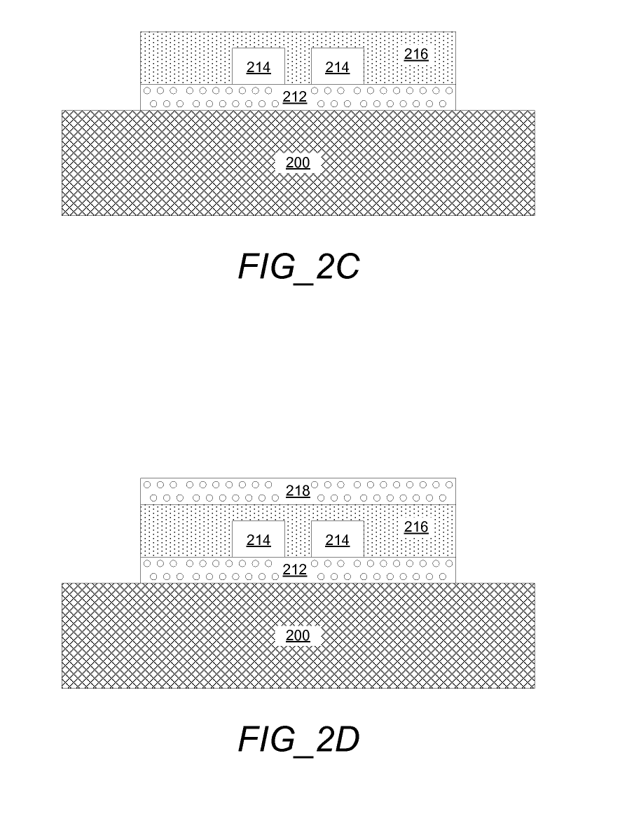

FIG. 1 is a method 100 of forming an ISVR device using a nano-encapsulated magnetic particle suspension in accordance with an implementation of the invention. FIGS. 2A to 2D illustrate structures that are formed when the method 100 of FIG. 1 is carried out.

The method 100 of FIG. 1 begins by providing a passivated integrated circuit (IC) device upon which an ISVR device may be fabricated (process 102 of method 100). The IC device is built on a semiconductor substrate formed using a single-crystal silicon or a silicon-on-insulator (SOI) substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, or gallium antimonide. Although a few examples of materials from which the substrate may be formed are described here, any material that may serve as a foundation upon which a semiconductor device may be built falls within the spirit and scope of the present invention.

Components such as transistors, inductors, and diodes may be formed on the surface of the substrate or within layers formed on the substrate. The semiconductor substrate generally includes one or more layers of material on its surface, such as semiconductive layers, dielectric layers, and conductive layers that have been photolithographically patterned and etched to form semiconductor device features over, on, or within the substrate. The semiconductive layers may include one or more of epitaxial silicon, polysilicon, amorphous silicon, doped polysilicon, or the like.

The dielectric layers may be formed using materials known for the applicability in dielectric layers for integrated circuit structures, such as one or more of silicon dioxide (SiO₂), fluorinated SiO₂, carbon doped oxide (CDO), silicon nitride (SiN), tetraethylorthosilicate (TEOS), borophosphosilicate glass (BPSG), fluorosilicate glass (FSG), spin on glass (SOG), low-k materials, high-k materials, organic polymers such as perfluorocyclobutane or polytetrafluoroethylene, inorganic polymers, and organosilicates such as silsesquioxane, siloxane, or organosilicate glass. The dielectric layer may include pores or other voids to further reduce its dielectric constant.

The conductive layers include metal interconnects and metal vias. These structures are generally formed of one or more of refractory silicides, refractory metals, aluminum, copper, tungsten, alloys of these materials, conductive nitrides, conductive oxides, or the like. Each conductive layer also includes interlayer dielectric (ILD) material surrounding and insulating the metal interconnects and the vias.

A passivation layer is formed over the above described layers of the IC device to seal and protect these layers. The passivation layer is generally formed of silicon nitride and may contain vias that electrically couple components within the IC device to components outside of the IC device.

FIG. 2A is a detailed illustration of an IC device 200 upon which the ISVR may be formed. Generally, the IC device 200 is built on a semiconductor substrate 202. The substrate 202 is generally formed using any of the materials described above. A top surface of the substrate 202 provides a device layer 204 upon which transistors, as well as other devices such as capacitors and inductors, may be formed. Above the device layer 204 are multiple metallization layers 206-1 through 206-n, where n represents the total number of metallization layers. Conventional IC devices can have as few as one metallization layer to as many as ten metallization layers, although greater than ten metallization layers are also possible. Each metallization layer 206 includes metal interconnects, generally formed of copper, as well as vias that electrically couple metal interconnects across various metallization layers. Each metallization layer 206 also includes interlayer dielectric (ILD) material surrounding and insulating the metal interconnects and the vias.

On the final metallization layer 206-n are a number of bond pads 208. One or more interconnects of the metallization layers 206 terminate at the bond pads 208, which are generally formed of copper, aluminum, or alloys thereof. A passivation layer 210 is formed above the metallization layers 206 to seal and protect the IC device 200 and the metallization layers 206 from damage and contamination. The passivation layer 210 may be formed from many different materials, including but not limited to silicon nitride (SiN), oxynitride, polyimide, and certain polymers. As is known in the art, openings may be formed in the passivation layer 210 to expose the bond pads 208.

Returning to FIG. 1, a nano-encapsulated magnetic particle (NEMP) suspension is formed (104). In one implementation of the invention, the NEMP suspension may be formed by dispersing nano-encapsulated magnetic particles into a dielectric material such as methylsilsequioxane (MSSQ), which is a known spin-on glassy material that readily polymerizes into a high strength and insulating ILD material. The nano-encapsulated magnetic particles consist of magnetic particles encased in nano-encapsulation shells. The magnetic particles may be formed using magnetic metals that include, but are not limited to, cobalt, nickel, and iron. For instance, Fe₄N is a soft magnetic material that may be used here. Another example is FeCoN, which is also a soft magnetic material. The nano-encapsulation shells are protective shells formed using a material such as aluminum oxide. The nano-encapsulation shell protects the magnetic particles from oxidation and loss of magnetic moment. The resulting NEMP suspension tends to be a homogenous mixture that provides both insulating and magnetic properties. As mentioned above, in addition to aluminum oxide, the nano-encapsulation shell may be formed using materials that include, but are not limited to, silicon dioxide, silicon nitride, tantalum nitride, titanium nitride, fluorinated silicon dioxide, carbon doped oxide, TEOS, BPSG, FSG, SOG, low-k materials, high-k materials, organic polymers such as perfluorocyclobutane and polytetrafluoroethylene, inorganic polymers, and organosilicates such as silsesquioxane, siloxane, and organosilicate glass.

The weight fraction of nano-encapsulated magnetic particles to dielectric material may range from 30% to 70%, depending on the variables such as the desired magnetic properties of the material, the specific metals used for the magnetic particles, and the specific dielectric material that is chosen. Other factors may be taken into consideration as well.

As noted above, in accordance with implementations of the invention, the NEMP suspension may be used to form the MCM layers of the ISVR. Therefore, the method 100 continues by using a spin-coating deposition process to deposit a first layer of the NEMP suspension onto the IC device (106). The NEMP suspension is typically formed on the passivation layer of the IC device, although in alternate implementations it may be deposited on a layer other than the passivation layer.

In implementations of the invention, the spin-coating deposition process may be adjusted to address issues that may arise, such as the NEMP suspension developing thixotropic properties at relatively high magnetic particle loadings. The adjustments that may be made include dilution of the NEMP suspension with MSSQ or common organic solvents including PGMEA, methyl isobutyl ketone (MIBK), chloroform, chlorobenzene, common alcohols (e.g., isopropanol, ethanol, and methanol), and toluene. Reflow agents may also be used to dilute the NEMP suspension. Further, the NEMP suspension may be adjusted using additional processing such as planarization, chemical mechanical polishing, annealing, spinning, laser ablation, or chemical etching. These processes may be used to improve film thickness uniformity across the surface of the wafer.

Next, the NEMP suspension that has been deposited on the IC device is cured using ultraviolet (UV) radiation (108). In some implementations, a thermal anneal may be used in lieu of UV curing. In one implementation, the thermal anneal may occur at around 150° C. in an ambient atmosphere. The UV or thermal cure promotes polymerization of the MSSQ into a glassy, amorphous, and low-k dielectric material, thereby forming a composite layer consisting of the glassy dielectric layer having the nano-encapsulated magnetic particles dispersed throughout its matrix. The composite layer therefore provides both insulating functionality and magnetic functionality. The nano-encapsulation shells continue to protect the magnetic particles from oxidation and loss of magnetic moment. For ease of reference, this composite layer will be referred to herein as a “NEMP composite layer”.

In some implementations of the invention, the thickness and uniformity of the NEMP composite layer may be increased by spin-depositing and curing one or more additional layers of the NEMP suspension.

The NEMP composite layer is used as an MCM layer for the ISVR device being fabricated by the method 100 of FIG. 1. More specifically, the NEMP composite layer that has been formed on the passivation layer of the IC device is the first NEMP composite layer and may be used as the first MCM layer 306 of the ISVR 300 in FIG. 3. In some implementations of the invention, after curing, the first NEMP composite layer may be etched using conventional photolithographic processes to form the first MCM layer.

In an alternate implementation, prior to the spin-coating deposition of the NEMP suspension in process 106, a patterned photoresist mask may formed that defines areas of the IC device where the first MCM layer is to be formed. For instance, conventional methods for depositing and patterning a photoresist material may be used to form a photoresist mask with at least one opening that exposes the underlying IC device. This opening defines where the first MCM layer is to be formed, and the spin-coating deposition process will fill this opening with the NEMP suspension. A planarization process may be used to remove excess material from the field of the photoresist mask.

FIG. 2B illustrates a NEMP composite layer 212 formed on the IC device 200. For clarity, the entire IC device 200 is represented by a single box rather than the detailed structure shown in FIG. 2A. In accordance with implementations of the invention, the NEMP composite layer 212 consists of a glassy, amorphous dielectric layer having nano-encapsulated magnetic particles dispersed throughout. The NEMP composite layer provides functionality that is equivalent to a conventional MCM layer used in ISVR applications. In implementations of the invention, the NEMP composite layer 212 may have a thickness that ranges from around 1000 nm to around 5000 nm. In some implementations, the NEMP composite layer 212 may have a thickness that is greater than 5000 nm.

One or more inductor wires may be formed atop the NEMP composite layer (110). Conventional metal deposition processes may be used to form the inductor wires, such as dual damascene processes that are well known in the art. The inductor wires may be formed using conventional metals used in semiconductor applications, including but not limited to copper and aluminum. An insulating material, such as an interlayer dielectric material, may then be formed over the inductor wires (112). This dielectric material may be any known dielectric material suitable for use here, such as any of the dielectric materials described herein. FIG. 2C illustrates a pair of inductor wires 214 that have been formed over the NEMP composite layer 212. An insulating layer 216, formed from a dielectric material, is formed over and around the inductor wires 214.

The fabrication of the ISVR continues by using a spin-coating deposition process to deposit a second layer of the NEMP suspension on the IC device (114). Here, the NEMP suspension is deposited on the interlayer dielectric that surrounds the inductor wires. As with the previous spin-coating deposition, adjustments may be made to address any thixotropic issues that have arisen, such as dilution of the NEMP suspension, addition of a reflow agent, or the addition of a planarization step to the process flow. The NEMP suspension is then cured using ultraviolet radiation or thermal anneal, thereby forming a second NEMP composite layer over the inductor wires (116). Again, the thickness of this NEMP composite layer may be increased by spin-depositing and curing one or more additional layers of the NEMP suspension.

This second NEMP composite layer that that has been formed over the inductor wires may be used as the second MCM layer 312 of the ISVR 300 in FIG. 3. In some implementations of the invention, after curing, the NEMP composite layer may be etched using conventional photolithographic processes to form the second MCM layer. In an alternate implementation, prior to the spin-coating deposition of the NEMP suspension in process 114, a patterned photoresist mask may formed that exposes areas of the IC device where the NEMP suspension is to be deposited and the second MCM layer is to be formed.

FIG. 2D illustrates a second NEMP composite layer 218 formed on the insulating layer 216. In accordance with implementations of the invention, the second NEMP composite layer 218 consists of a glassy, amorphous dielectric layer having nano-encapsulated magnetic particles dispersed throughout its matrix. The NEMP composite layer provides functionality that is equivalent to a conventional MCM layer used in ISVR applications. In implementations of the invention, the NEMP composite layer 218 may have a thickness that ranges from around 1000 nm to around 5000 nm. In some implementations, the NEMP composite layer 218 may have a thickness that is greater than 5000 nm.

Accordingly, a novel NEMP composite layer has been described that may be applied using spin-coat deposition and curing processes and provides both magnetic and insulating functionality. The NEMP composite layer provides improved device response time, an increased number of power states, and low impedance access to the transistors. The use of a nano-encapsulation shell on the magnetic particles prevents oxidation and loss of magnetic moment. Finally, the NEMP suspension provides in-situ conversion of magnetic material to insulator.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method of forming an integrated silicon voltage regulator (ISVR) comprising:
providing a nano-encapsulated magnetic particle (NEMP) suspension;
depositing a first layer of the NEMP suspension on an integrated circuit (IC) device;
curing the first layer of the NEMP suspension to form a first NEMP composite layer;
forming at least one inductor wire on the NEMP composite layer;
depositing an interlayer dielectric material over the inductor wire;
depositing a second layer of the NEMP suspension on the interlayer dielectric material; and
curing the second layer of the NEMP suspension to form a second NEMP composite layer.

2. The method of claim 1, wherein the providing of the NEMP suspension comprises:
combining nano-encapsulated magnetic particles and a dielectric material.

3. The method of claim 2, wherein the dielectric material comprises methylsilsequioxane (MSSQ).

4. The method of claim 2, wherein the nano-encapsulated magnetic particles comprise magnetic particles selected from the group consisting of cobalt, nickel, and iron and a nano-encapsulation shell selected from the group consisting of aluminum oxide, silicon dioxide, silicon nitride, tantalum nitride, titanium nitride, fluorinated silicon dioxide, carbon doped oxide, TEOS, BPSG, FSG, SOG, a low-k material, a high-k material, an organic polymer, perfluorocyclobutane, polytetrafluoroethylene, an inorganic polymer, an organosilicate, silsesquioxane, siloxane, and organosilicate glass.

5. The method of claim 1, wherein the depositing of the first and second layers of the NEMP suspension comprises using a spin-coat deposition process.

6. The method of claim 5, wherein the spin-coat deposition further comprises at least one of diluting the NEMP suspension, adding a reflow agent to the NEMP suspension, and planarizing the NEMP suspension.

7. The method of claim 1, wherein the curing of the NEMP suspension comprises exposing the NEMP suspension to ultraviolet radiation or thermally annealing the NEMP suspension.

8. The method of claim 1, further comprising etching the first NEMP composite layer to form a first magnetic core material layer for the integrated silicon voltage regulator.

9. The method of claim 1, further comprising etching the second NEMP composite layer to form a second magnetic core material layer for the integrated silicon voltage regulator.

10. A method of forming an integrated silicon voltage regulator (ISVR) comprising:
depositing a first layer of photoresist material on an IC device;
patterning the first layer of photoresist material to form a first opening that exposes a potion of the IC device where the ISVR is to be formed;
providing a nano-encapsulated magnetic particle (NEMP) suspension;
depositing a first layer of the NEMP suspension in the first opening;
curing the first layer of the NEMP suspension to form a first NEMP composite layer;
forming at least one inductor wire on the NEMP composite layer;
depositing an interlayer dielectric material over the inductor wire;
depositing a second layer of photoresist material on the interlayer dielectric material;
patterning the second layer of photoresist material to form a second opening that exposes a potion of the interlayer dielectric over the inductor wire;
depositing a second layer of the NEMP suspension in the second opening; and
curing the second layer of the NEMP suspension to form a second NEMP composite layer.

11. The method of claim 10, wherein the dielectric material comprises methylsilsequioxane (MSSQ).

12. The method of claim 10, wherein the nano-encapsulated magnetic particles comprise magnetic particles selected from the group consisting of cobalt, nickel, and iron and a nano-encapsulation shell selected from the group consisting of aluminum oxide, silicon dioxide, silicon nitride, tantalum nitride, titanium nitride, fluorinated silicon dioxide, carbon doped oxide, TEOS, BPSG, FSG, SOG, a low-k material, a high-k material, an organic polymer, perfluorocyclobutane, polytetrafluoroethylene, an inorganic polymer, an organosilicate, silsesquioxane, siloxane, and organosilicate glass.

13. An apparatus comprising:
a first NEMP composite layer formed on an IC device;
an inductor wire formed on the first NEMP composite layer;
an interlayer dielectric material formed over the inductor wire; and
a second NEMP composite layer formed on the interlayer dielectric material.

14. The apparatus of claim 13, wherein the first and second NEMP composite layers comprise a plurality of nano-encapsulated magnetic particles dispersed throughout a cured dielectric material.

15. The apparatus of claim 14, wherein the magnetic particles are chosen from the group consisting of cobalt, nickel, and iron, wherein a nano-encapsulation shell on the magnetic particles is selected from the group consisting of aluminum oxide, silicon dioxide, silicon nitride, tantalum nitride, titanium nitride, fluorinated silicon dioxide, carbon doped oxide, TEOS, BPSG, FSG, SOG, a low-k material, a high-k material, an organic polymer, perfluorocyclobutane, polytetrafluoroethylene, an inorganic polymer, an organosilicate, silsesquioxane, siloxane, and organosilicate glass, and wherein the cured dielectric material comprises MSSQ.
